(19) United States
(12) Patent Application Publication
(10) Pub. No.: US 2025/0155466 A1
(43) Pub. Date: May 15, 2025

(54) Method For Manufacturing Electronic Device

(71) Applicant: SEIKO EPSON CORPORATION, Tokyo (JP)

(72) Inventor: Hitoshi UENO, Shiojiri (JP)

(21) Appl. No.: 18/945,781

(22) Filed: Nov. 13, 2024

(30) Foreign Application Priority Data
Nov. 14, 2023 (JP) 2023-193502

(51) Int. Cl. G01P 1/02; H05K 1/18; H05K 3/30

(52) U.S. Cl. CPC G01P 1/023; G01P 1/026; H05K 1/181; H05K 3/303; H05K 2201/10151

(57) ABSTRACT

In a method for manufacturing an electronic device, a first electronic device includes a first sensor, a second sensor, a first circuit board, and a first package, a second electronic device includes a third sensor, a fourth sensor, a second circuit board, and a second package, the first package and the second package have the same size in plan view, the second sensor has a size smaller than a size of the fourth sensor in plan view, the first circuit board and the second circuit board have the same size in plan view, and the method includes: mounting the first circuit board on the first package and then mounting the second sensor; and mounting the fourth sensor on the second package and then mounting the second circuit board.

The present application is based on, and claims priority from JP Application Serial Number 2023-193502, filed Nov. 14, 2023, the disclosure of which is hereby incorporated by reference herein in its entirety.

### BACKGROUND

### 1. Technical Field

The present disclosure relates to a method for manufacturing an electronic device.

### 2. Related Art

JP-A-2017-40619 discloses, as an example of an electronic device, a composite sensor that houses an angular velocity sensor, an acceleration sensor, and a circuit board in a single package. An angular velocity and an acceleration are physical quantities.

Even sensors that detect the same type of physical quantity may have different sensor sizes depending on required detection accuracy or the like. The number of package types tends to increase due to size variations of sensors and circuit boards.

### SUMMARY

A method for manufacturing an electronic device is a method for manufacturing a plurality of electronic devices including a first electronic device and a second electronic device, the first electronic device including a first sensor that detects a first physical quantity, a second sensor that detects a second physical quantity different from the first physical quantity, a first circuit board that is electrically coupled to the first sensor and the second sensor, and a first package that houses the first sensor, the second sensor, and the first circuit board, the second electronic device including a third sensor that detects the first physical quantity, a fourth sensor that detects the second physical quantity, a second circuit board that is electrically coupled to the third sensor and the fourth sensor, and a second package that houses the third sensor, the fourth sensor, and the second circuit board, the first package and the second package having the same size in plan view, the first sensor and the third sensor having the same size in plan view, the second sensor having a size smaller than a size of the fourth sensor in plan view, and the first circuit board and the second circuit board having the same size in plan view, the method including: mounting the first circuit board on the first package and then mounting the second sensor on the first circuit board; and mounting the fourth sensor on the second package and then mounting the second circuit board on the fourth sensor.

### BRIEF DESCRIPTION OF THE DRAWINGS

FIG. 1 is a perspective view illustrating a first electronic device.

FIG. 2 is a perspective view illustrating a second electronic device.

FIG. 3 is an exploded perspective view illustrating the first electronic device.

FIG. 4 is a perspective view illustrating a first case.

FIG. 5 is a plan view illustrating the first case.

FIG. 6 is a perspective view illustrating the first case and a third electronic component.

FIG. 7 is a perspective view illustrating the first case, a second electronic component, and the third electronic component.

FIG. 8 is a cross-sectional view illustrating the first electronic device.

FIG. 9 is an exploded perspective view illustrating a first electronic component.

FIG. 10 is a plan view illustrating a sensor element.

FIG. 11 is a plan view illustrating the sensor element.

FIG. 12 is a plan view illustrating a support portion.

FIG. 13 is a perspective view illustrating the first case.

FIG. 14 is a plan view for describing a configuration of the second electronic component.

FIG. 15 is a plan view for describing a first acceleration sensor.

FIG. 16 is a plan view for describing a second acceleration sensor.

FIG. 17 is a plan view for describing a third acceleration sensor.

FIG. 18 is a schematic view for describing a cross-sectional configuration of the second electronic component.

FIG. 19 is a cross-sectional view illustrating the first electronic device.

FIG. 20 is a perspective view illustrating the second electronic device.

FIG. 21 is a plan view illustrating a second case, a fifth electronic component, and a sixth electronic component.

FIG. 22 is a cross-sectional view illustrating the second electronic device.

FIG. 23 is a flowchart illustrating an example of a method for manufacturing the first electronic device and the second electronic device.

FIG. 24 is a flowchart illustrating an example of a method for manufacturing the first electronic device.

FIG. 25 is a flowchart illustrating an example of a method for manufacturing the second electronic device.

### DESCRIPTION OF EMBODIMENTS

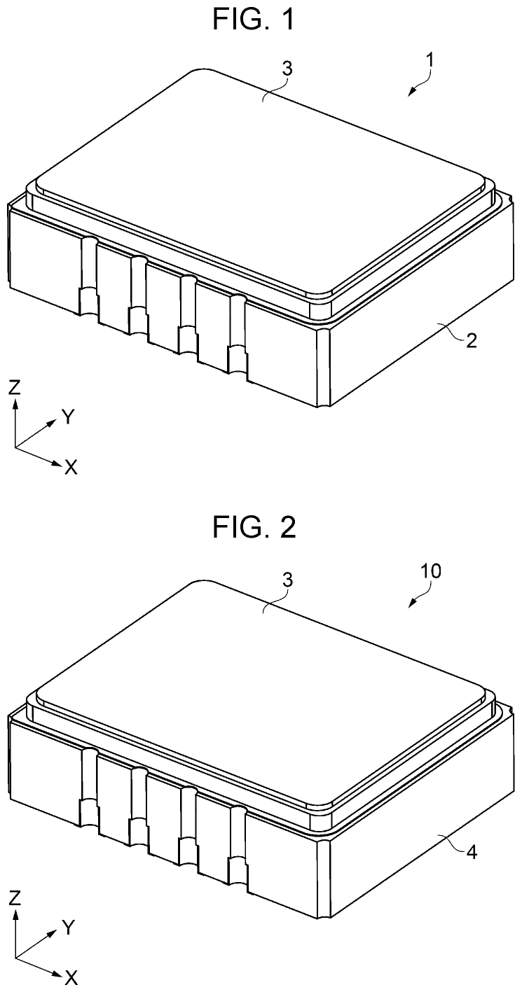

As illustrated in FIG. 1, a first electronic device 1 includes a first case 2 and a lid 3. The lid 3 is stacked on the first case 2. The first case 2 is an example of a first package. As illustrated in FIG. 2, a second electronic device 10 includes a second case 4 and a lid 3. The lid 3 is stacked on the second case 4. The second case 4 is an example of a second package. The lid 3 of the first electronic device 1 and the lid 3 of the second electronic device 10 are the same components. An X axis, a Y axis, and a Z axis are indicated in FIG. 1 and FIG. 2. The X axis, the Y axis, and the Z axis are mutually orthogonal coordinate axes. The X axis, the Y axis, and the Z axis are also indicated as necessary in the drawings following FIGS. 1 and 2. In this case, the X axis, the Y axis, and the Z axis in each drawing correspond to the X axis, the Y axis, and the Z axis in FIGS. 1 and 2. FIG. 1 illustrates a state where the first electronic device 1 is mounted on an X-Y plane defined by the X axis and the Y axis. FIG. 2 illustrates a state where the second electronic device 10 is mounted on the X-Y plane defined by the X axis and the Y axis.

Hereinafter, the X axis, the Y axis, and the Z axis indicated in a drawing or description of a component or unit of the first electronic device 1 mean the X axis, the Y axis, and the Z axis in a state where the component or unit is incorporated in the first electronic device 1. The X axis, the Y axis, and the Z axis indicated in a drawing or description of a component or unit of the second electronic device 10 mean the X axis, the Y axis, and the Z axis in a state where the component or unit is incorporated in the second electronic device 10. Each of the X axis, the Y axis, and the Z axis is indicated by an arrow. For each of the X axis, the Y axis, and the Z axis, a direction in which the arrow is directed indicates a +(positive) direction, and a direction opposite to the direction in which the arrow is directed indicates a −(negative) direction. The Z axis is an axis orthogonal to the X-Y plane. Plan views of the first electronic device 1 and the second electronic device 10 are views when viewed in a −Z direction.

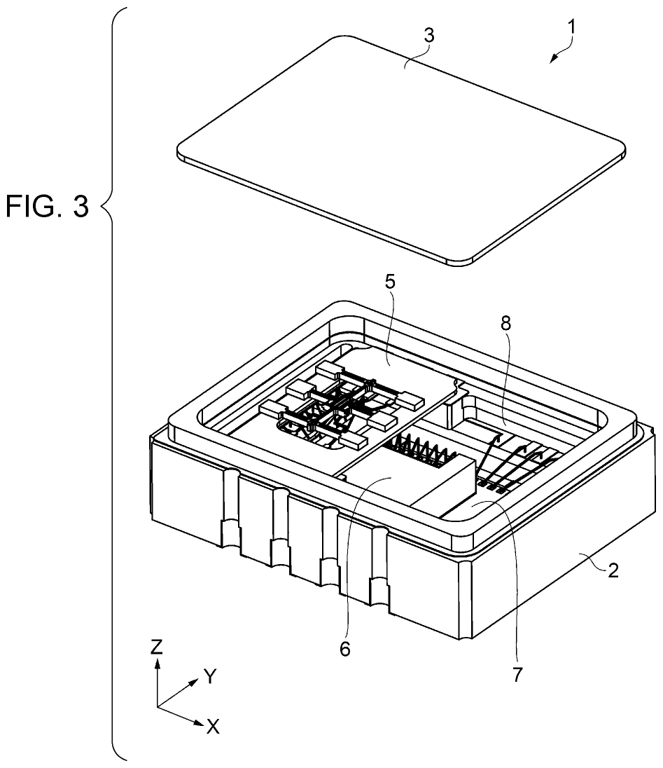

As illustrated in FIG. 3, the first electronic device 1 further includes a first electronic component 5, a second electronic component 6, and a third electronic component 7. The first electronic component 5 is an example of a first sensor. The second electronic component 6 is an example of a second sensor. The third electronic component 7 is an example of a first circuit board. The first electronic component 5, the second electronic component 6, and the third electronic component 7 are housed inside the first case 2. The first case 2 has a recessed cavity 8 formed therein. The first electronic component 5, the second electronic component 6, and the third electronic component 7 are housed in the cavity 8 of the first case 2.

The first case 2 can be formed, for example, by sintering a ceramic substrate. The cavity 8 can be formed by stacking a plurality of ceramic substrates. The lid 3 may be formed using, for example, various metal plates. The first case 2 is closed by the lid 3 in a state where the first electronic component 5, the second electronic component 6, and the third electronic component 7 are housed in the cavity 8 of the first case 2. The first case 2 and the lid 3 are bonded to each other by, for example, seam welding.

Each of the first electronic component 5 and the second electronic component 6 is a sensor that detects a motion of an object on which the first electronic device 1 is installed. The first electronic component 5 detects an angular velocity of the object. The second electronic component 6 detects an acceleration of the object. The angular velocity is an example of a first physical quantity. The acceleration is an example of a second physical quantity. The third electronic component 7 is a circuit board that controls the first electronic component 5 and the second electronic component 6. The third electronic component 7 processes detection signals output from the first electronic component 5 and the second electronic component 6. The third electronic component 7 controls signals for driving the first electronic component 5 and the second electronic component 6.

The first electronic component 5 detects the angular velocity of the object around the Z axis. In the present embodiment, the first electronic component 5 is a gyro sensor. The second electronic component 6 includes three acceleration sensors. The three acceleration sensors are an acceleration sensor that detects an acceleration along the Y axis, an acceleration sensor that detects an acceleration along the X axis, and an acceleration sensor that detects an acceleration along the Z axis. For example, a capacitive acceleration sensor can be used as the acceleration sensor. Furthermore, for example, a quartz acceleration sensor can be used as the acceleration sensor.

All of the three acceleration sensors may be capacitive acceleration sensors. All of the three acceleration sensors may be quartz acceleration sensors. The three acceleration sensors may be a combination of capacitive acceleration sensors and quartz acceleration sensors. In the present embodiment, all of the three acceleration sensors are capacitive acceleration sensors. The number of acceleration sensors included in the second electronic component 6 is not limited to three. The number of acceleration sensors included in the second electronic component 6 may be two. The number of acceleration sensors included in the second electronic component 6 may be one.

The third electronic component 7 is implemented by, for example, an integrated circuit (IC). The third electronic component 7 processes various signals output from the first electronic component 5 and the second electronic component 6. The third electronic component 7 includes various circuits for processing various signals output from the first electronic component 5 and the second electronic component 6. Various circuit elements that configure various circuits are formed in the third electronic component 7. The second electronic component 6 is positioned in a +Z direction with respect to the third electronic component 7. The second electronic component 6 is mounted in the +Z direction with respect to the third electronic component 7.

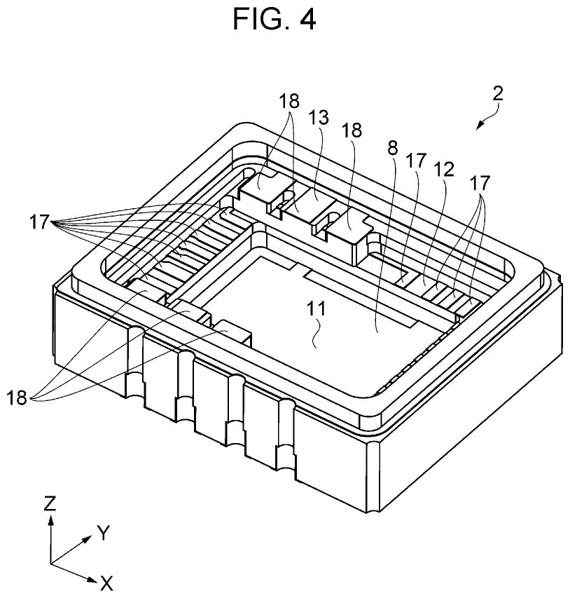

As illustrated in FIG. 4, the first case 2 has a bottom surface 11, a first step portion 12, and a second step portion 13 inside the cavity 8. The bottom surface 11 forms a bottom of the cavity 8. The first step portion 12 is positioned in the +Z direction with respect to the bottom surface 11. The first step portion 12 surrounds the bottom surface 11 along an inner periphery of the cavity 8 in plan view. The first step portion 12 has a frame shape surrounding the bottom surface 11 of the cavity 8 in plan view. The second step portion 13 is positioned in the +Z direction with respect to the first step portion 12.

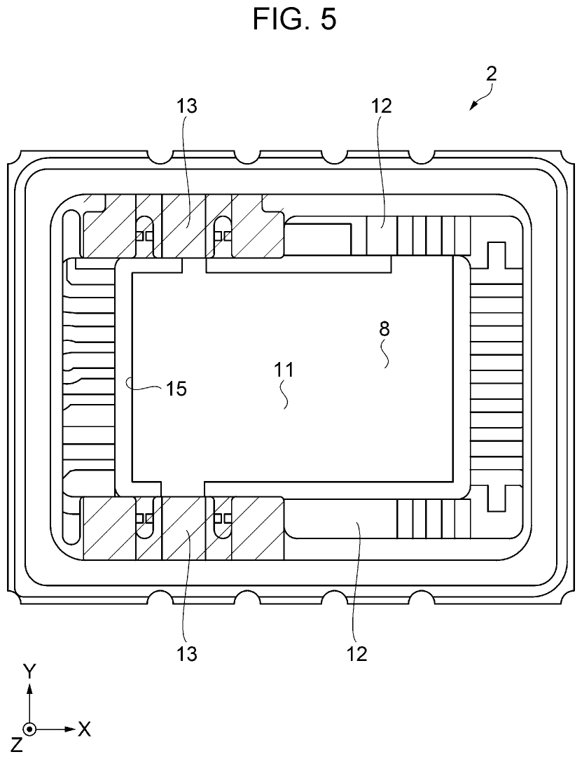

As illustrated in FIG. 5, the second step portion 13 is provided at each of two or more positions that face each other across the bottom surface 11 in plan view. In FIG. 5, the second step portion 13 is hatched to clearly show the configuration. The first step portion 12 protrudes further inward into the cavity 8 than the second step portion 13 except for a portion of the second step portion 13 where a sensor wiring 18 (described below) is provided. The bottom surface 11, the first step portion 12, and the second step portion 13 can be visually recognized in plan view of the first case 2. The first step portion 12 is positioned outside the bottom surface 11 in plan view. The second step portion 13 is provided at a position overlapping the first step portion 12 in plan view. The second step portion 13 overlaps a part of the first step portion 12 in plan view.

Various electrodes and wirings are formed in the first case 2. A power supply wiring 15 is formed on the bottom surface 11. Various terminal electrodes (not illustrated) are formed on a back surface of the first case 2. The power supply wiring 15 is electrically coupled to the terminal electrode formed on the back surface of the first case 2 via a wiring pattern (not illustrated). A driving voltage for driving the first electronic device 1 is applied to the power supply wiring 15. In addition to the terminal electrode coupled to the power supply wiring 15, a terminal electrode for outputting the detection signal output from the first electronic component 5 or the second electronic component 6 is also formed on the back surface of the first case 2. The terminal electrodes formed on the back surface of the first case 2 also include a ground terminal that is grounded to a reference potential.

As illustrated in FIG. 4, a plurality of first electrode pads 17 are formed on the first step portion 12. The third electronic component 7 is electrically coupled to the plurality of first electrode pads 17. A plurality of sensor wirings 18 are formed on the second step portion 13. The first electronic component 5 is electrically coupled to the plurality of sensor wirings 18. Some of the plurality of first electrode pads 17 are electrically coupled to some of the plurality of sensor wirings 18 via the wiring pattern (not illustrated). Various electric signals are transmitted between the first electronic component 5 and the third electronic component 7 via some of the plurality of first electrode pads 17 and some of the plurality of sensor wirings 18.

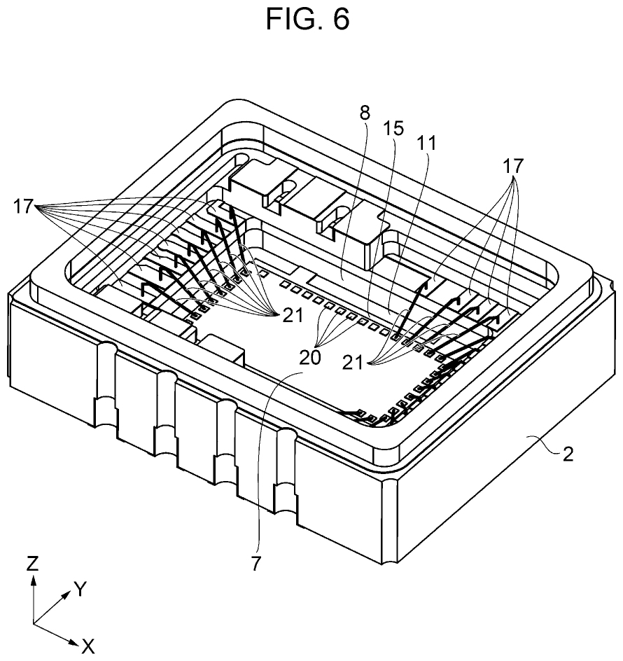

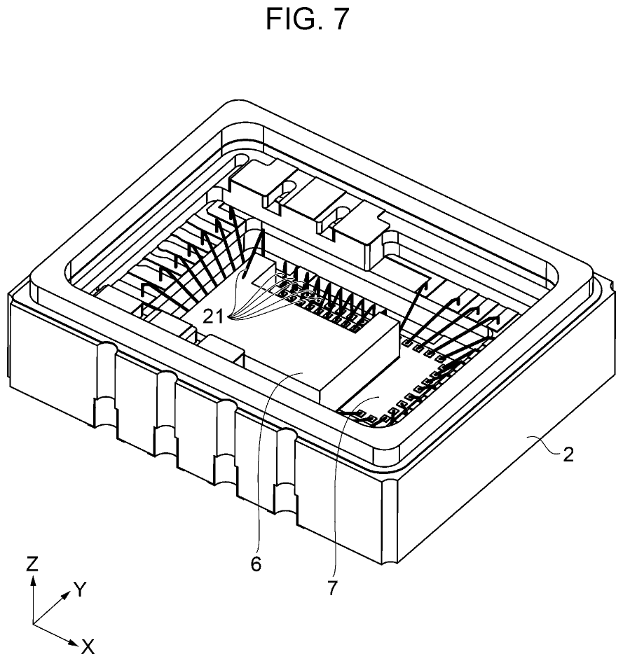

As illustrated in FIG. 6, the third electronic component 7 is disposed on the bottom surface 11 of the cavity 8. The third electronic component 7 is positioned in the +Z direction with respect to the bottom surface 11. The third electronic component 7 includes plurality of electrode pads 20. The electrode pad 20 is an example of a bonding pad. A wire 21 is coupled to each of the electrode pads 20. The plurality of electrode pads 20 of the third electronic component 7 are electrically coupled to the first electrode pads 17 by using the wires 21, respectively. As illustrated in FIG. 7, the second electronic component 6 is disposed in the +Z direction with respect to the third electronic component 7. The second electronic component 6 is mounted on the third electronic component 7. The second electronic component 6 is electrically coupled to the third electronic component 7 by the plurality of wires 21.

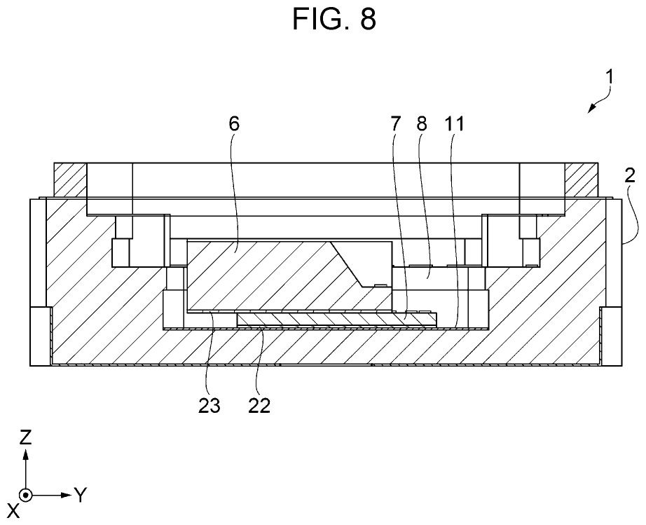

As illustrated in FIG. 8, the third electronic component 7 is bonded to the bottom surface 11 of the cavity 8 by using a die attachment film 22. The second electronic component 6 is bonded to the third electronic component 7 by using a die attachment film 23. The die attachment film 23 is an example of a first die attachment film. The second electronic component 6 protrudes from the third electronic component 7 in a −Y direction. A portion of the second electronic component 6 protrudes from the third electronic component 7 in the −Y direction. In other words, a portion of the second electronic component 6 is positioned outside a region overlapping the third electronic component 7 in plan view in the −Z direction.

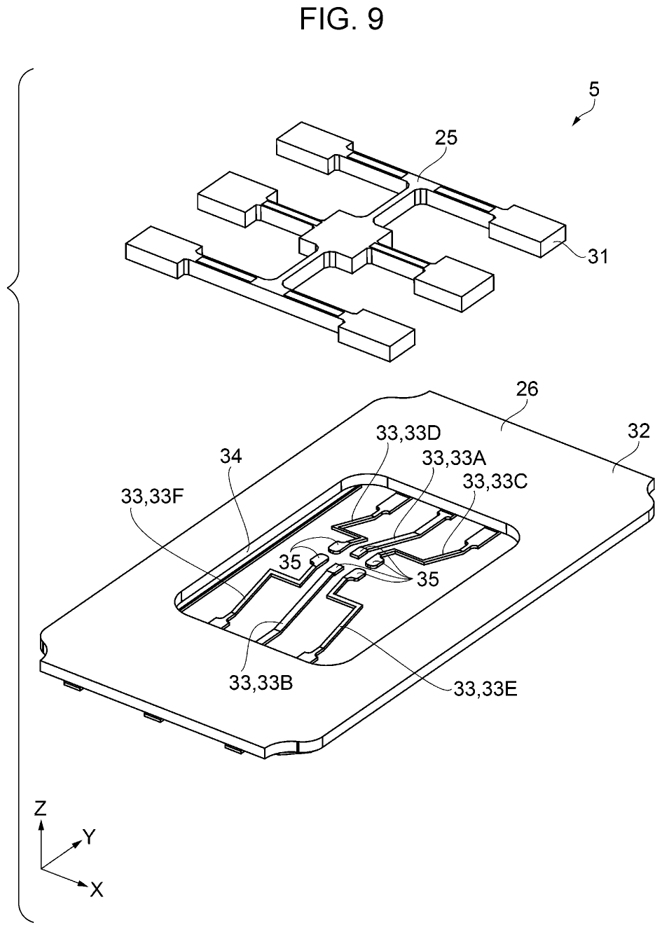

As illustrated in FIG. 9, the first electronic component 5 includes a sensor element 25 and a support portion 26. The sensor element 25 includes a vibration element 31. The vibration element 31 is formed from a quartz substrate. The vibration element 31 is formed from, for example, a Z-cut quartz substrate. In the present embodiment, the vibration element 31 has a double T-shaped structure. The support portion 26 includes an insulating member 32 and a plurality of leads 33. The plurality of leads 33 include a first drive lead 33A, a second drive lead 33B, a first detection lead 33C, a second detection lead 33D, a first ground lead 33E, and a second ground lead 33F.

The insulating member 32 is formed of, for example, a polyimide resin. The insulating member 32 is formed in a sheet shape. A metal wiring pattern (not illustrated) is printed on the insulating member 32. The plurality of leads 33 are electrically coupled to the wiring pattern of the insulating member 32. A device hole 34 is formed in the insulating member 32. The plurality of leads 33 extend from the insulating member 32 toward the inside of the device hole 34 in plan view. The plurality of leads 33 are bent. The plurality of leads 33 protrude in the +Z direction from the insulating member 32 toward the inside of the device hole 34. The support portion 26 is a tape automated bonding (TAB) tape. The plurality of leads 33 are spaced apart from each other. An end portion 35 of each of the plurality of leads 33 is positioned inside the device hole 34 in plan view. The end portion 35 is positioned in the +Z direction with respect to the insulating member 32. The sensor element 25 is electrically coupled to the end portions 35 of the plurality of leads 33.

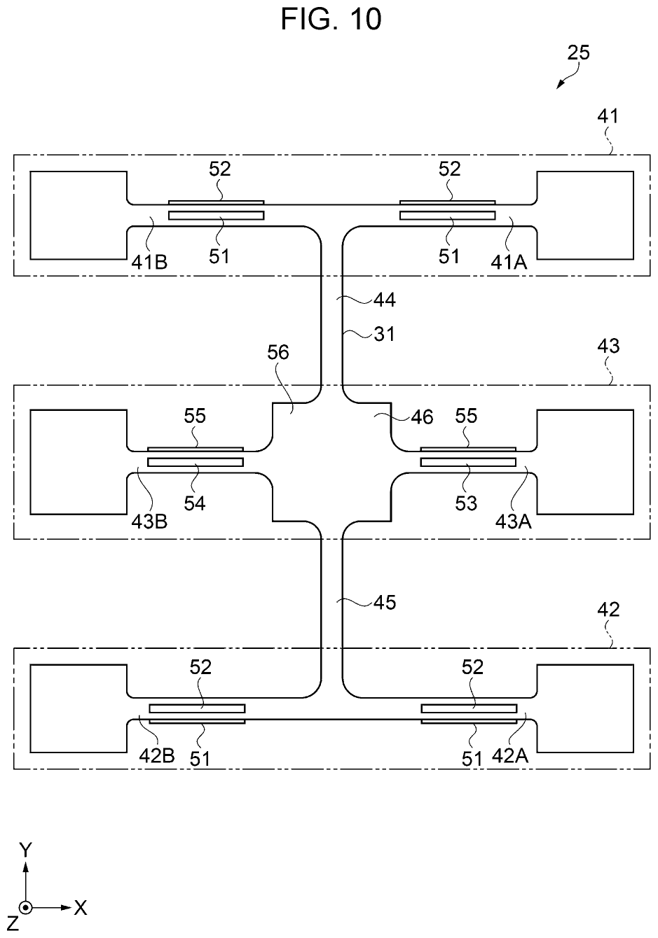

As illustrated in FIG. 10, the sensor element 25 includes a first drive portion 41, a second drive portion 42, an angular velocity detection portion 43, a first connecting arm 44, and a second connecting arm 45. The first drive portion 41 includes a first drive arm 41A and a second drive arm 41B. The second drive portion 42 includes a third drive arm 42A and a fourth drive arm 42B. The angular velocity detection portion 43 includes a base portion 46, a first detection arm 43A, and a second detection arm 43B. The first detection arm 43A extends from the base portion 46 in a +X direction. The second detection arm 43B extends from the base portion 46 in a −X direction. The first drive portion 41 is positioned in a +Y direction with respect to the angular velocity detection portion 43. The second drive portion 42 is positioned in the −Y direction with respect to the angular velocity detection portion 43.

The first drive portion 41 is connected to the base portion 46 by the first connecting arm 44. The second drive portion 42 is connected to the base portion 46 by the second connecting arm 45. The first connecting arm 44 extends from the base portion 46 in the +Y direction. The second connecting arm 45 extends from the base portion 46 in the −Y direction. The first drive arm 41A extends from the first connecting arm 44 in the +X direction. The second drive arm 41B extends from the first connecting arm 44 in the −X direction. The first drive portion 41 can also be considered to be divided into the first drive arm 41A and the second drive arm 41B by the first connecting arm 44. The third drive arm 42A extends from the second connecting arm 45 in the +X direction. The fourth drive arm 42B extends from the second connecting arm 45 in the −X direction. The second drive portion 42 can also be considered to be divided into the third drive arm 42A and the fourth drive arm 42B by the second connecting arm 45.

The first drive portion 41 includes a first drive electrode 51 and a second drive electrode 52. The second drive portion 42 also includes a first drive electrode 51 and a second drive electrode 52. The first drive electrode 51 of the first drive portion 41 and the first drive electrode 51 of the second drive portion 42 are electrically coupled to each other. The first drive electrode 51 is an electrode common to the first drive portion 41 and the second drive portion 42. The second drive electrode 52 of the first drive portion 41 and the second drive electrode 52 of the second drive portion 42 are electrically coupled to each other. The second drive electrode 52 is an electrode common to the first drive portion 41 and the second drive portion 42.

The angular velocity detection portion 43 includes a first detection electrode 53, a second detection electrode 54, and common electrodes 55. The first detection electrode 53 is provided on the first detection arm 43A. The second detection electrode 54 is provided on the second detection arm 43B. The common electrodes 55 are provided on the first detection arm 43A and the second detection arm 43B. The common electrode 55 of the first detection arm 43A and the common electrode 55 of the second detection arm 43B are electrically coupled to each other. The first detection electrode 53 is provided on a surface of the first detection arm 43A that faces the +Z direction. The surface that faces the +Z direction is also called a main surface 56 of the vibration element 31. The second detection electrode 54 is provided on a main surface 56 of the second detection arm 43B. The common electrode 55 of the first detection arm 43A is provided on a side surface of the first detection arm 43A that faces the +Y direction. The common electrode 55 of the second detection arm 43B is provided on a side surface of the second detection arm 43B that faces the +Y direction. The common electrode 55 is grounded to a ground which is the reference potential.

The first drive electrodes 51 are provided on the first drive arm 41A, the second drive arm 41B, the third drive arm 42A, and the fourth drive arm 42B. The second drive electrodes 52 are also provided on the first drive arm 41A, the second drive arm 41B, the third drive arm 42A, and the fourth drive arm 42B. The first drive electrode 51 of the first drive arm 41A and the first drive electrode 51 of the second drive arm 41B are both provided on the main surface 56. The second drive electrode 52 of the first drive arm 41A and the second drive electrode 52 of the second drive arm 41B are both provided on the side surfaces that face the +Y direction.

The first drive electrode 51 of the third drive arm 42A and the first drive electrode 51 of the fourth drive arm 42B are both provided on side surfaces that face the −Y direction. The second drive electrode 52 of the third drive arm 42A and the second drive electrode 52 of the fourth drive arm 42B are both provided on the main surface 56. An alternating current (AC) excitation signal is applied between the first drive electrode 51 and the second drive electrode 52. The arrangement of the first drive electrode 51 and the arrangement of the second drive electrode 52 are opposite to each other in the first drive portion 41 and the second drive portion 42.

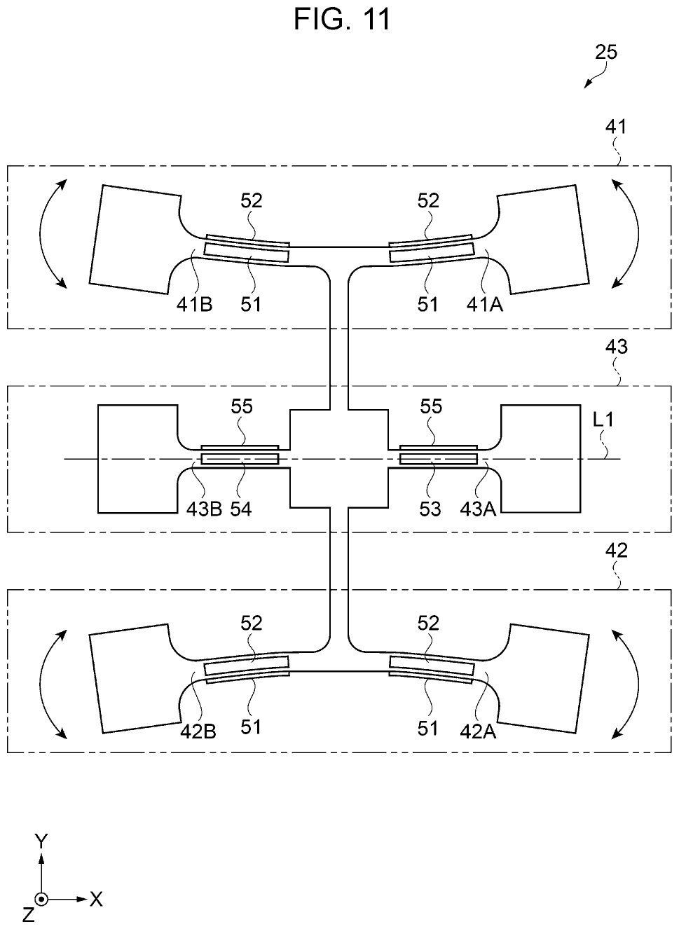

With such an electrode arrangement, the first drive portion 41 and the second drive portion 42 vibrate in a linearly symmetrical manner with respect to an axial line L1 along the X axis that passes through the angular velocity detection portion 43 as illustrated in FIG. 11. The linearly symmetrical vibration of the first drive portion 41 and the second drive portion 42 with respect to the axial line L1 means that the first drive arm 41A and the third drive arm 42A move toward and away from each other. The linearly symmetrical vibration of the first drive portion 41 and the second drive portion 42 with respect to the axial line L1 means that the second drive arm 41B and the fourth drive arm 42B move toward and away from each other.

When the first drive portion 41 and the second drive portion 42 vibrate and an angular velocity around the Z axis is generated in the sensor element 25, a Coriolis force acts on the first drive portion 41 and the second drive portion 42. The Coriolis force acting on the first drive portion 41 and the second drive portion 42 causes vibration of the first detection arm 43A and the second detection arm 43B. As the first detection arm 43A and the second detection arm 43B vibrate, a detection signal is output from each of the first detection electrode 53 and the second detection electrode 54. The detection signal output from the first detection electrode 53 and the detection signal output from the second detection electrode 54 are in opposite phase to each other.

The detection signal output from the first detection electrode 53 is referred to as a first detection signal. The detection signal output from the second detection electrode 54 is referred to as a second detection signal. The first detection signal and the second detection signal form a differential signal. The angular velocity is detected based on a differential amplified signal which is a signal obtained by amplifying a difference between the first detection signal and the second detection signal. When the angular velocity around the Z axis is generated in the sensor element 25, the first detection signal and the second detection signal are in opposite phase to each other. At this time, the differential amplified signal of the first detection signal and the second detection signal is amplified to twice the first detection signal and the second detection signal. The angular velocity is detected based on the differential amplified signal.

When no angular velocity is generated in the sensor element 25, that is, when the sensor element 25 is in a stationary state, the first detection signal and the second detection signal are both at the reference potential. When the sensor element 25 is in the stationary state, the differential amplified signal of the first detection signal and the second detection signal is not output. Therefore, no angular velocity is detected. When the sensor element 25 moves linearly along the Y axis, the first detection signal and the second detection signal are in phase with each other. Therefore, the first detection signal and the second detection signal are cancelled by the differential amplification. Therefore, no angular velocity is detected.

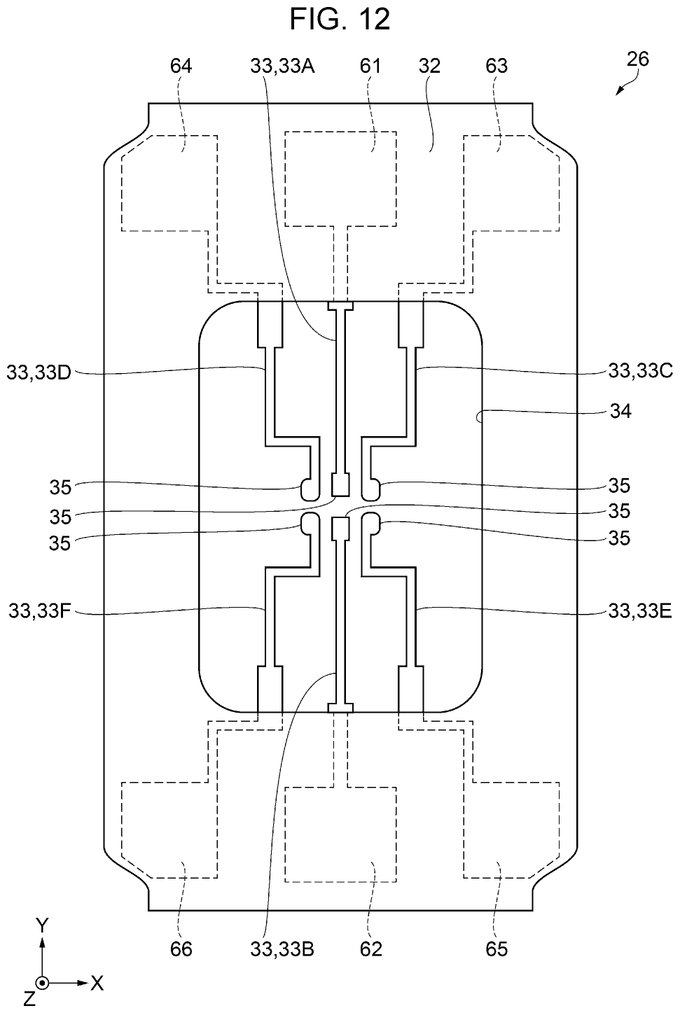

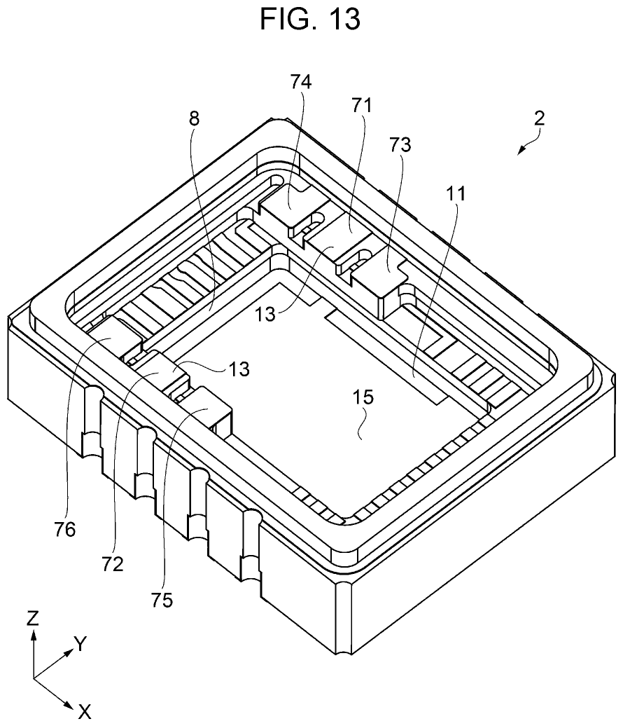

As illustrated in FIG. 12, the support portion 26 includes a first drive terminal 61, a second drive terminal 62, a first detection terminal 63, a second detection terminal 64, a first ground terminal 65, and a second ground terminal 66. The first drive terminal 61, the second drive terminal 62, the first detection terminal 63, the second detection terminal 64, the first ground terminal 65, and the second ground terminal 66 are provided on a surface of the insulating member 32 that faces the −Z direction. The first drive terminal 61, the second drive terminal 62, the first detection terminal 63, the second detection terminal 64, the first ground terminal 65, and the second ground terminal 66 are terminal electrodes formed on the insulating member 32.

The first drive terminal 61 is electrically connected to the first drive electrode 51 illustrated in FIG. 10 via the first drive lead 33A. The second drive terminal 62 is electrically connected to the second drive electrode 52 illustrated in FIG. 10 via the second drive lead 33B. The first detection terminal 63 is electrically connected to the first detection electrode 53 illustrated in FIG. 10 via the first detection lead 33C. The second detection terminal 64 is electrically connected to the second detection electrode 54 illustrated in FIG. 10 via the second detection lead 33D. The first ground terminal 65 is electrically connected to the common electrode 55 illustrated in FIG. 10 via the first ground lead 33E. The second ground terminal 66 is a spare terminal electrode. The second ground terminal 66 is grounded to the ground potential. The second ground terminal 66 may be electrically coupled to the sensor element 25 via the second ground lead 33F.

A drive signal, which is an excitation signal, is applied from the third electronic component 7 to the first drive terminal 61 and the second drive terminal 62 illustrated in FIG. 12. The drive signal is applied from the first drive terminal 61 to the first drive electrode 51 via the first drive lead 33A. The drive signal is applied from the second drive terminal 62 to the second drive electrode 52 via the second drive lead 33B. The first detection signal output from the first detection electrode 53 is input to the third electronic component 7 via the first detection lead 33C and the first detection terminal 63. The second detection signal output from the second detection electrode 54 is input to the third electronic component 7 via the second detection lead 33D and the second detection terminal 64. The common electrode 55 is grounded to the ground potential via the first ground lead 33E and the first ground terminal 65.

As illustrated in FIG. 13, a first drive pad 71, a second drive pad 72, a first detection pad 73, a second detection pad 74, a first ground pad 75, and a second ground pad 76 are formed on the second step portion 13 of the first case 2. The first drive pad 71, the second drive pad 72, the first detection pad 73, the second detection pad 74, the first ground pad 75, and the second ground pad 76 are formed on a surface of the second step portion 13 that faces the +Z direction. The first drive pad 71, the second drive pad 72, the first detection pad 73, the second detection pad 74, the first ground pad 75, and the second ground pad 76 each extend along the X-Y plane. The first drive pad 71, the second drive pad 72, the first detection pad 73, the second detection pad 74, the first ground pad 75, and the second ground pad 76 are each a part of the sensor wiring 18 illustrated in FIG. 4.

The first electronic component 5 is mounted on the first drive pad 71, the second drive pad 72, the first detection pad 73, the second detection pad 74, the first ground pad 75, and the second ground pad 76 illustrated in FIG. 13. The first drive terminal 61 illustrated in FIG. 12 is electrically coupled to the first drive pad 71 by a bonding material such as a solder. The second drive terminal 62 is electrically coupled to the second drive pad 72 by a bonding material such as a solder. The first detection terminal 63 is electrically coupled to the first detection pad 73 by a bonding material such as a solder. The second detection terminal 64 is electrically coupled to the second detection pad 74 by a bonding material such as a solder. The first ground terminal 65 is electrically coupled to the first ground pad 75 by a bonding material such as a solder. The second ground terminal 66 is electrically coupled to the second ground pad 76 by a bonding material such as a solder.

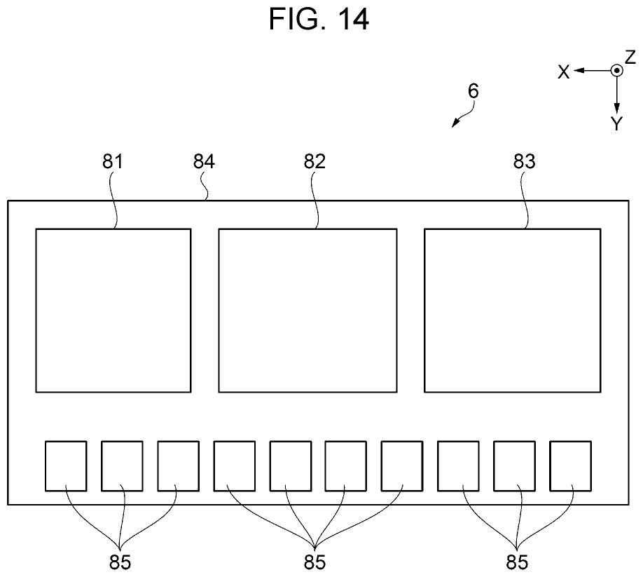

As illustrated in FIG. 14, the second electronic component 6 includes a first acceleration sensor 81, a second acceleration sensor 82, and a third acceleration sensor 83. The first acceleration sensor 81 detects an acceleration along the Z axis. The second acceleration sensor 82 detects an acceleration along the X axis. The third acceleration sensor 83 detects an acceleration along the Y axis. The first acceleration sensor 81, the second acceleration sensor 82, and the third acceleration sensor 83 are formed on one silicon substrate 84. A plurality of electrode pads 85 are formed on the silicon substrate 84.

In the example illustrated in FIG. 14, the first acceleration sensor 81, the second acceleration sensor 82, and the third acceleration sensor 83 are arranged along the X axis. The first acceleration sensor 81 is positioned in the +X direction with respect to the second acceleration sensor 82. The second acceleration sensor 82 is positioned in the +X direction with respect to the third acceleration sensor 83. The order in which the first acceleration sensor 81, the second acceleration sensor 82, and the third acceleration sensor 83 are arranged is not limited to that in the example illustrated in FIG. 14. The first acceleration sensor 81, the second acceleration sensor 82, and the third acceleration sensor 83 can be arranged in any order.

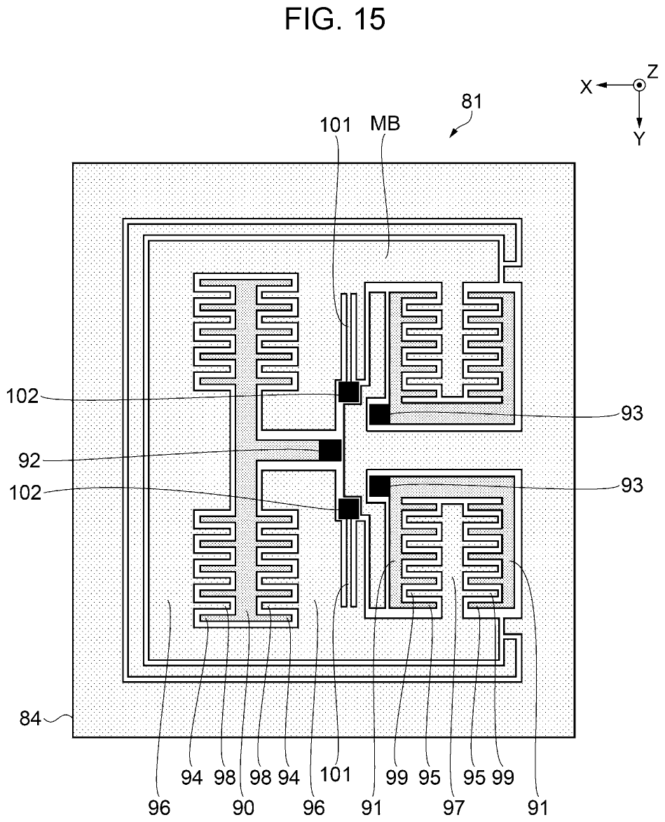

As illustrated in FIG. 15, the first acceleration sensor 81 includes a fixed electrode portion 90, a fixed electrode portion 91, a movable body MB, a fixed electrode fixing portion 92, and a fixed electrode fixing portion 93. The fixed electrode portion 90 includes a plurality of fixed electrodes 94, and the fixed electrode portion 91 includes a plurality of fixed electrodes 95. The movable body MB includes a movable electrode portion 96 and a movable electrode portion 97. The movable electrode portion 96 of the movable body MB includes a movable electrode 98. The movable electrode portion 97 includes a movable electrode 99. The fixed electrode 94, the fixed electrode 95, the movable electrode 98, and the movable electrode 99 are each electrically coupled to the electrode pad 85 illustrated in FIG. 14. Each of the movable electrode portion 96 and the movable electrode portion 97 is an example of a detection portion.

The movable body MB is movable relative to the silicon substrate 84 in response to an acceleration or the like applied from the outside. The first acceleration sensor 81 includes a support beam 101 and a fixing portion 102. The movable body MB is connected to the silicon substrate 84 via the support beam 101 and the fixing portion 102. The support beam 101 is, for example, a torsion spring. One end of the support beam 101 is coupled to the fixing portion 102, and the other end of the support beam 101 is coupled to the movable body MB. The fixing portion 102 is an example of an anchor portion.

The fixing portion 102 is electrically coupled to the movable body MB via the support beam 101. As the support beam 101 is twisted in response to an acceleration or the like applied from the outside, the movable body MB can perform a seesaw motion relative to the silicon substrate 84. The seesaw motion of the movable body MB changes a capacitance between the fixed electrode portion 90 and the movable electrode portion 96, and a capacitance between the fixed electrode portion 91 and the movable electrode portion 97. The change in capacitance between the fixed electrode portion 90 and the movable electrode portion 96, and the change in capacitance between the fixed electrode portion 91 and the movable electrode portion 97 can be electrically detected via the electrode pads 85 illustrated in FIG. 14. The first acceleration sensor 81 can detect the acceleration along the Z axis based on the change in capacitance between the fixed electrode portion 90 and the movable electrode portion 96, and the change in capacitance between the fixed electrode portion 91 and the movable electrode portion 97.

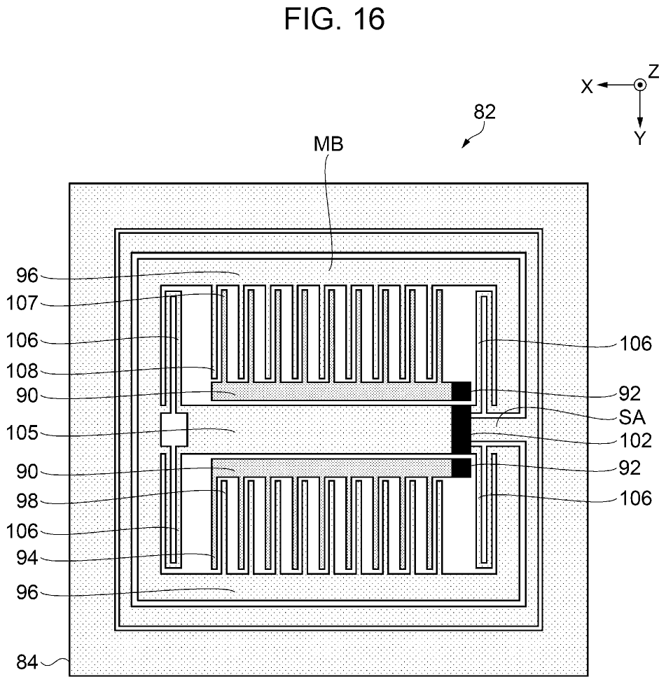

As illustrated in FIG. 16, the second acceleration sensor 82 includes a movable electrode support portion 105, a fixing portion 102, a plurality of support springs 106, and a wiring structure SA. The movable electrode support portion 105 extends along the X axis. The fixing portion 102 is provided on one end side of the movable electrode support portion 105. The fixing portion 102 fixes the movable electrode portion 96 via the support springs 106. Two of the plurality of support springs 106 extend from the fixing portion 102. The remaining two of the plurality of support springs 106 extend from the other end of the movable electrode support portion 105 on a side opposite to the fixing portion 102. Each of the plurality of support springs 106 is coupled to the movable body MB.

Two fixed electrode portions 90 are positioned on opposite sides of the movable electrode support portion 105, respectively. One of the two fixed electrode portions 90 includes the fixed electrode 94, and the other of the two fixed electrode portions 90 includes a fixed electrode 107, the fixed electrode 94 and the fixed electrode 107 having mutually different polarities. One of the movable electrode portions 96 positioned on opposite sides of the movable electrode support portion 105 includes the movable electrode 98, and the other includes a movable electrode 108. The movable electrode 98 and the fixed electrode 94 form a pair. The movable electrode 108 and the fixed electrode 107 form a pair. The fixing portion 102 of the movable electrode portion 96 and the fixed electrode fixing portion 92 of the fixed electrode portion 90 each have a cantilever structure supported at one point. The fixed electrode fixing portions 92 are provided adjacent to opposite sides of the fixing portion 102, respectively.

When the acceleration along the X axis is applied, the movable electrode portion 96 vibrates along the X axis relative to the silicon substrate 84. At this time, a capacitance between the movable electrode 98 and the fixed electrode 94, and a capacitance between the movable electrode 108 and the fixed electrode 107 change. The change in capacitance between the movable electrode 98 and the fixed electrode 94, and the change in capacitance between the movable electrode 108 and the fixed electrode 107 can be electrically detected via the electrode pads 85 illustrated in FIG. 14. The second acceleration sensor 82 can detect the acceleration along the X axis based on the change in capacitance between the movable electrode 98 and the fixed electrode 94, and the change in capacitance between the movable electrode 108 and the fixed electrode 107.

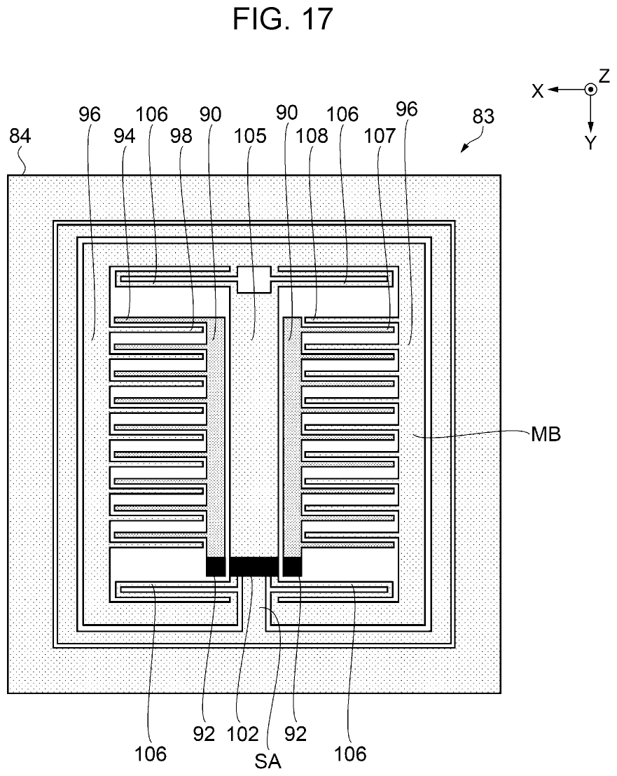

As illustrated in FIG. 17, in the third acceleration sensor 83, a movable electrode support portion 105 extends along the Y axis. The third acceleration sensor 83 has the same configuration as the second acceleration sensor 82 illustrated in FIG. 16. In other words, the second acceleration sensor 82 and the third acceleration sensor 83 are the same elements. As illustrated in FIG. 17, the third acceleration sensor 83 is arranged in a different direction from the second acceleration sensor 82. When an acceleration is applied to the third acceleration sensor 83, a movable electrode portion 96 vibrates along the Y axis relative to the silicon substrate 84.

At this time, a capacitance between a movable electrode 98 and a fixed electrode 94, and a capacitance between a movable electrode 108 and a fixed electrode 107 change. The change in capacitance between the movable electrode 98 and the fixed electrode 94, and the change in capacitance between the movable electrode 108 and the fixed electrode 107 can be electrically detected via the electrode pads 85 illustrated in FIG. 14. The third acceleration sensor 83 can detect the acceleration along the Y axis based on the change in capacitance between the movable electrode 98 and the fixed electrode 94, and the change in capacitance between the movable electrode 108 and the fixed electrode 107.

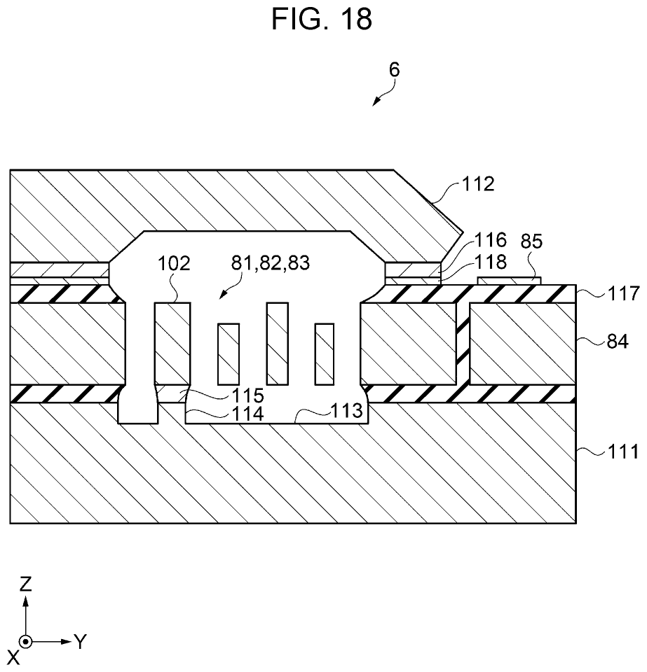

As illustrated in FIG. 18, the second electronic component 6 further includes a cavity substrate 111 and a cap substrate 112. The cavity substrate 111 is positioned in the −Z direction with respect to the silicon substrate 84. The cap substrate 112 is positioned in the +Z direction with respect to the silicon substrate 84. The silicon substrate 84 is held between the cavity substrate 111 and the cap substrate 112. A cavity 113 is formed in the cavity substrate 111. A plurality of support portions 114 are formed in the cavity 113. The support portions 114 protrude from a bottom portion of the cavity 113 in the +Z direction.

The same number of support portions 114 as the number of fixing portions 102 included in the silicon substrate 84 are formed in the cavity 113. The fixing portion 102 of each of the first acceleration sensor 81, the second acceleration sensor 82, and the third acceleration sensor 83 is bonded to each of the support portions 114 by a bonding agent 115. Each fixing portion 102 is fixed by each support portion 114. The cap substrate 112 covers the first acceleration sensor 81, the second acceleration sensor, and the third acceleration sensor 83 from the +Z direction.

The cap substrate 112 is bonded to the silicon substrate 84 via a glass frit 116. By doing so, a region surrounded by the cavity substrate 111 and the cap substrate 112 is kept airtight. An insulating layer 117 is interposed between the glass frit 116 and the silicon substrate 84. Various electrodes formed on the silicon substrate 84 are electrically coupled to the electrode pads 85 via a wiring 118 passing between the insulating layer 117 and the glass frit 116.

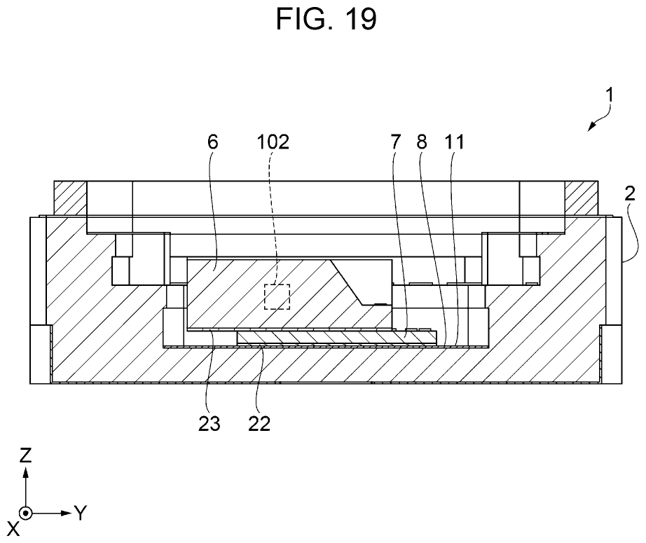

As illustrated in FIG. 19, in the first electronic device 1, all of the fixing portions 102 of the second electronic component 6 are positioned in the +Z direction with respect to the third electronic component 7. The third electronic component 7 is positioned in the −Z direction with respect to each fixing portion 102 of the second electronic component 6. In other words, all of the fixing portions 102 of the second electronic component 6 are positioned within a region overlapping the third electronic component 7 in plan view in the −Z direction. With such a configuration, the fixing portions 102 of the second electronic component 6 can be supported by the third electronic component 7, so that detection accuracy of the second electronic component 6 is likely to be stable.

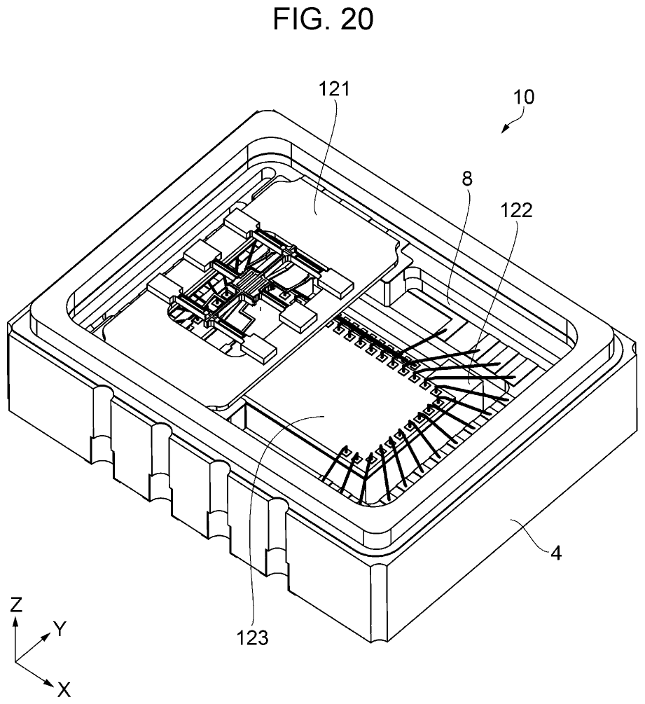

As illustrated in FIG. 20, the second electronic device 10 further includes a fourth electronic component 121, a fifth electronic component 122, and a sixth electronic component 123. The fourth electronic component 121 is an example of a third sensor. The fifth electronic component 122 is an example of a fourth sensor. The sixth electronic component 123 is an example of a second circuit board. The fourth electronic component 121, the fifth electronic component 122, and the sixth electronic component 123 are housed inside the second case 4. The second case 4 has a recessed cavity 8 formed therein. The fourth electronic component 121, the fifth electronic component 122, and the sixth electronic component 123 are housed in the cavity 8 of the second case 4. A size of the second case 4 is the same as a size of the first case 2 in plan view. In the present embodiment, the first case 2 and the second case 4 are the same components. Therefore, components of the second case 4 are denoted by the same reference numerals as those of the first case 2, and a detailed description thereof will be omitted.

The fourth electronic component 121 and the fifth electronic component 122 are sensors that detect a motion of an object on which the second electronic device 10 is installed. The fourth electronic component 121 detects an angular velocity of the object. The fifth electronic component 122 detects an acceleration of the object. The sixth electronic component 123 is a circuit board that controls the fourth electronic component 121 and the fifth electronic component 122. The sixth electronic component 123 processes detection signals output from the fourth electronic component 121 and the fifth electronic component 122. The sixth electronic component 123 controls signals for driving the fourth electronic component 121 and the fifth electronic component 122.

The fourth electronic component 121 detects the angular velocity of the object around the Z axis. In the present embodiment, the fourth electronic component 121 is a gyro sensor. A size of the fourth electronic component 121 is the same as a size of the first electronic component 5 in plan view. In the present embodiment, the first electronic component 5 and the fourth electronic component 121 are the same components. Therefore, components of the fourth electronic component 121 are denoted by the same reference numerals as those of the first electronic component 5, and a detailed description thereof will be omitted.

The fifth electronic component 122 includes three acceleration sensors. The three acceleration sensors are an acceleration sensor that detects an acceleration along the Y axis, an acceleration sensor that detects an acceleration along the X axis, and an acceleration sensor that detects an acceleration along the Z axis. For example, a capacitive acceleration sensor can be used as the acceleration sensor. Furthermore, for example, a quartz acceleration sensor can be used as the acceleration sensor. A size of the fifth electronic component 122 is larger than a size of the second electronic component 6 in plan view. That is, the size of the second electronic component 6 is smaller than the size of the fifth electronic component 122 in plan view. The fifth electronic component 122 has the same configuration as the second electronic component 6, except for a difference in size. Therefore, components of the fifth electronic component 122 are denoted by the same reference numerals as those of the second electronic component 6, and a detailed description thereof will be omitted.

The sixth electronic component 123 is implemented by, for example, an integrated circuit (IC). The sixth electronic component 123 processes various signals output from the fourth electronic component 121 and the fifth electronic component 122. The sixth electronic component 123 includes various circuits for processing various signals output from the fourth electronic component 121 and the fifth electronic component 122. Various circuit elements that configure various circuits are formed in the sixth electronic component 123. The sixth electronic component 123 is positioned in the +Z direction with respect to the fifth electronic component 122. The sixth electronic component 123 is mounted in the +Z direction with respect to the fifth electronic component 122. A size of the sixth electronic component 123 is the same as a size of the third electronic component 7 in plan view. Components of the sixth electronic component 123 that are the same as those of the third electronic component 7 are denoted by the same reference numerals as those of the third electronic component 7, and a detailed description thereof will be omitted.

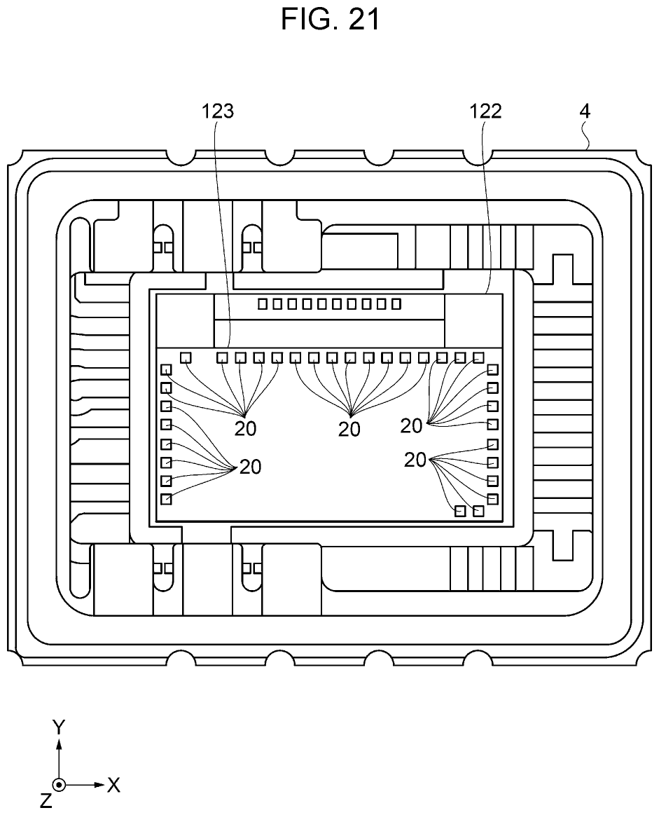

As illustrated in FIG. 21, the size of the sixth electronic component 123 is smaller than the size of the fifth electronic component 122 in plan view. A plurality of electrode pads 20 of the sixth electronic component 123 are positioned within a region overlapping the fifth electronic component 122 in plan view. With such a configuration, the plurality of electrode pads 20 of the sixth electronic component 123 can be supported by the fifth electronic component 122, and therefore, the electrode pads 20 can be easily stabilized when a wire 21 is connected to the electrode pads 20.

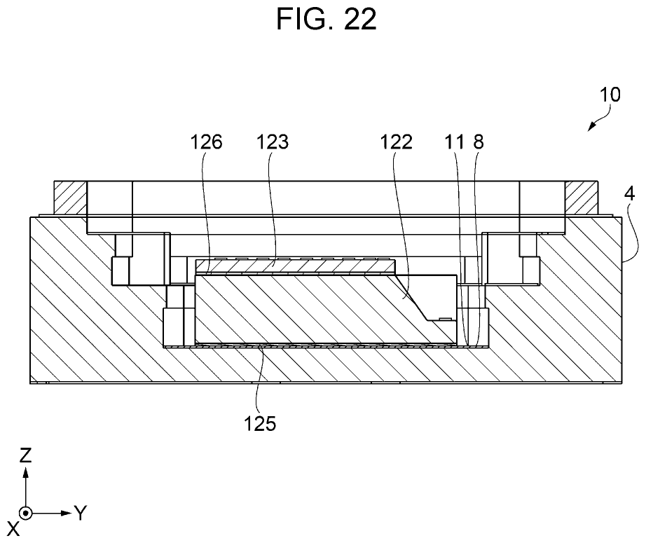

As illustrated in FIG. 22, the fifth electronic component 122 is bonded to a bottom surface 11 of the cavity 8 by using a die attachment film 125. The sixth electronic component 123 is bonded to the fifth electronic component 122 by using a die attachment film 126. The die attachment film 126 is an example of a second die attachment film.

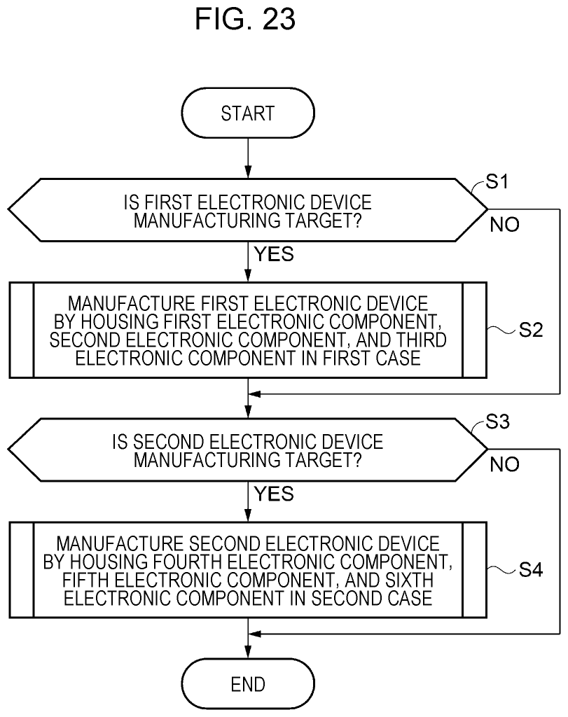

A method for manufacturing the first electronic device 1 and the second electronic device 10 will be described. As illustrated in FIG. 23, the method for manufacturing the first electronic device 1 and the second electronic device 10 includes steps S1, S2, S3, and S4. When it is determined in step S1 that the first electronic device 1 is a manufacturing target, the processing proceeds to step S2. Step S2 is a step of manufacturing the first electronic device 1 by housing the first electronic component 5, the second electronic component 6, and the third electronic component 7 in the first case 2.

When a determination result of step S1 is NO, the processing proceeds to step S3. When it is determined in step S3 that the second electronic device 10 is a manufacturing target, the processing proceeds to step S4. Step S4 is a step of manufacturing the second electronic device 10 by housing the fourth electronic component 121, the fifth electronic component 122, and the sixth electronic component 123 in the second case 4. When a determination result of step S3 is NO, the manufacturing of the first electronic device 1 and the second electronic device 10 is not performed.

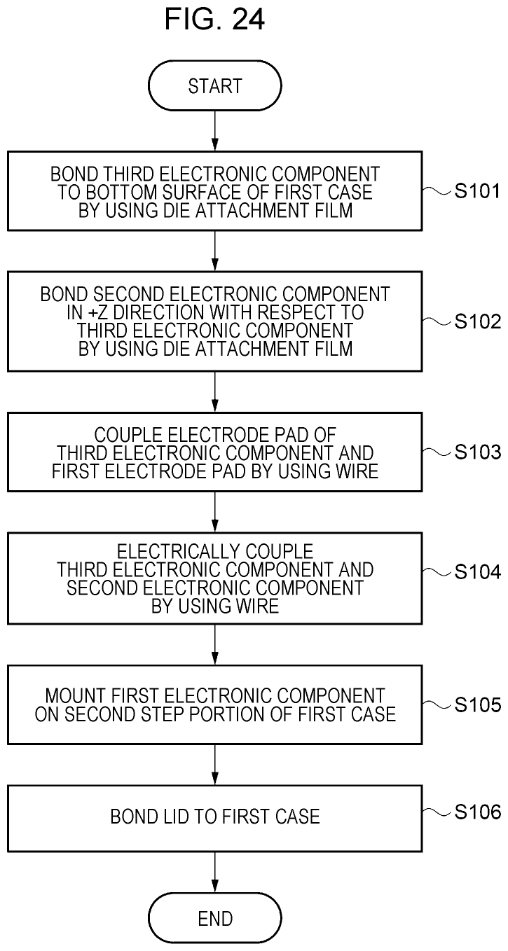

As illustrated in FIG. 24, the method for manufacturing the first electronic device 1 includes steps S101, S102, S103, S104, S105, and S106. The method for manufacturing the first electronic device 1 illustrated in FIG. 24 is a detailed flow of step S2 illustrated in FIG. 23. That is, step S2 includes steps S101, S102, S103, S104, S105, and S106 illustrated in FIG. 24.

Step S101 is a step of bonding the third electronic component 7 to the bottom surface 11 of the first case 2 by using the die attachment film 22. Step S102, which is a step following step S101, is a step of bonding the second electronic component 6 to the third electronic component 7 by using the die attachment film 23. In step S102, the second electronic component 6 is bonded in the +Z direction with respect to the third electronic component 7 by using the die attachment film 23. In step S102, when the second electronic component 6 is mounted in the +Z direction with respect to the third electronic component 7, the fixing portion 102 of the second electronic component 6 overlaps the third electronic component 7 in plan view.

Step S103, which is a step following step S102, is a step of coupling the electrode pad 20 of the third electronic component 7 and the first electrode pad 17 by using the wire 21. Step S104, which is a step following step S103, is a step of electrically coupling the third electronic component 7 and the second electronic component 6 by using the wire 21. In steps S103 and S104, the wire 21 is coupled by wire bonding using a bonding machine.

Step S105, which is a step following step S104, is a step of mounting the first electronic component 5 on the second step portion 13 of the first case 2. Step S106, which is a step following step S105, is a step of bonding the lid 3 to the first case 2. Step S106 may be performed in an atmospheric pressure environment or in a pressure environment lower than the atmospheric pressure. The first electronic device 1 is manufactured in this manner.

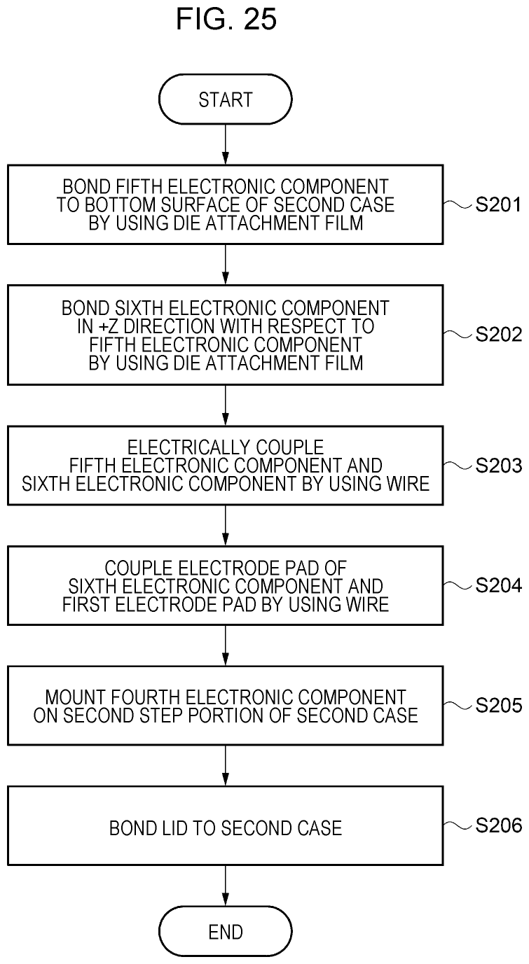

As illustrated in FIG. 25, the method for manufacturing the second electronic device 10 includes steps S201, S202, S203, S204, S205, and S206. The method for manufacturing the second electronic device 10 illustrated in FIG. 25 is a detailed flow of step S4 illustrated in FIG. 23. That is, step S4 includes steps S201, S202, S203, S204, S205, and S206 illustrated in FIG. 25.

Step S201 is a step of bonding the fifth electronic component 122 to the bottom surface 11 of the second case 4 by using the die attachment film 125. Step S202, which is a step following step S201, is a step of bonding the sixth electronic component 123 to the fifth electronic component 122 by using the die attachment film 126. In step S202, the sixth electronic component 123 is bonded in the +Z direction with respect to the fifth electronic component 122 by using the die attachment film 126. In step S202, when the sixth electronic component 123 is mounted in the +Z direction with respect to the fifth electronic component 122, the plurality of electrode pads 20 of the sixth electronic component 123 are positioned in a region overlapping the fifth electronic component 122 in plan view. Therefore, the plurality of electrode pads 20 of the sixth electronic component 123 can be supported by the fifth electronic component 122, and therefore, the electrode pads 20 can be easily stabilized when a wire 21 is connected to the electrode pads 20.

Step S203, which is a step following step S202, is a step of electrically coupling the fifth electronic component 122 and the sixth electronic component 123 by using the wire 21. Step S204, which is a step following step S203, is a step of coupling the electrode pad 20 of the sixth electronic component 123 and the first electrode pad 17 by using the wire 21. In steps S203 and S204, the wire 21 is coupled by wire bonding using a bonding machine.

Step S205, which is a step following step S204, is a step of mounting the fourth electronic component 121 on the second step portion 13 of the second case 4. Step S206, which is a step following step S205, is a step of bonding the lid 3 to the second case 4. Step S206 may be performed in an atmospheric pressure environment or in a pressure environment lower than the atmospheric pressure. The second electronic device 10 is manufactured in this manner.

According to the method for manufacturing of the first electronic device 1 and the second electronic device 10, both the first case 2 and the second case 4, which have the same size in plan view, can house both the second electronic component 6 and the fifth electronic component 122 having different sizes in plan view. In other words, according to the method for manufacturing the first electronic device 1 and the second electronic device 10, it is possible to house the fifth electronic component 122 in the first case 2 and house the second electronic component 6 in the second case 4. With the manufacturing method, it is easy to avoid an increase in the number of package types due to size variations of sensors and circuit boards.

What is claimed is:

1. A method for manufacturing a plurality of electronic devices including a first electronic device and a second electronic device,
the first electronic device including a first sensor that detects a first physical quantity, a second sensor that detects a second physical quantity different from the first physical quantity, a first circuit board that is electrically coupled to the first sensor and the second sensor, and a first package that houses the first sensor, the second sensor, and the first circuit board,
the second electronic device including a third sensor that detects the first physical quantity, a fourth sensor that detects the second physical quantity, a second circuit board that is electrically coupled to the third sensor and the fourth sensor, and a second package that houses the third sensor, the fourth sensor, and the second circuit board,
the first package and the second package having the same size in plan view,
the first sensor and the third sensor having the same size in plan view,
the second sensor having a size smaller than a size of the fourth sensor in plan view,
the first circuit board and the second circuit board having the same size in plan view,
the method comprising:
mounting the first circuit board on the first package and then mounting the second sensor on the first circuit board; and
mounting the fourth sensor on the second package and then mounting the second circuit board on the fourth sensor.

2. The method according to claim 1, wherein
the second circuit board includes a plurality of bonding pads, and
when the second circuit board is mounted on the fourth sensor, the plurality of bonding pads overlap the fourth sensor in plan view.

3. The method according to claim 1, wherein
the second sensor includes a detection portion that is displaced according to the second physical quantity, and an anchor portion that supports the detection portion, and
when the second sensor is mounted on the first circuit board, the anchor portion overlaps the first circuit board in plan view.

4. The method according to claim 3, wherein when the second sensor is mounted on the first circuit board, a part of the second sensor is positioned outside a region overlapping the first circuit board in plan view.

5. The method according to claim 1, further comprising:
bonding the first circuit board and the second sensor by using a first die attachment film; and
bonding the fourth sensor and the second circuit board by using a second die attachment film.
